(19) United States
(12) Patent Application Publication
(10) Pub. No.: US 2025/0351448 A1
(43) Pub. Date: Nov. 13, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Tsung Han HSU, Hsinchu (TW); Po-Cheng CHEN, Yilan (TW); Kuan-Chang CHIU, Hsinchu (TW); Wen-Long LEE, Hsinchu (TW); Chung-Chiang WU, Taichung (TW)

(21) Appl. No.: 18/825,784

(22) Filed: Sep. 5, 2024

Related U.S. Application Data
(60) Provisional application No. 63/645,186, filed on May 10, 2024.

(51) Int. Cl. H01L 29/423; H01L 21/02; H01L 21/304; H01L 21/8238; H01L 27/092; H01L 29/06; H01L 29/66; H01L 29/775; H01L 29/786

(52) U.S. Cl. CPC H10D 30/6735; H01L 21/02208; H01L 21/0228; H01L 21/304; H10D 30/014; H10D 30/43; H10D 30/6757; H10D 62/121; H10D 84/0172; H10D 84/038; H10D 84/85

(57) ABSTRACT

Embodiments of the present disclosure provide a semiconductor device structure and methods of forming the same. The method includes forming a fin structure from a substrate, and the fin structure includes a plurality of semiconductor layers. The method further includes depositing a gate dielectric layer around a portion of each semiconductor layer of the plurality of semiconductor layers, depositing an adhesion layer on the gate dielectric layer, and the adhesion layer surrounds the portion of each semiconductor layer of the plurality of semiconductor layers. The method further includes depositing a fluorine-containing layer on the adhesion layer, and the fluorine-containing layer surrounds the portion of each semiconductor layer of the plurality of semiconductor layers. The method further includes performing an annealing process on the fluorine-containing layer, removing the fluorine-containing layer and the adhesion layer, and forming a gate electrode layer on the gate dielectric layer.

### CROSS-REFERENCE TO RELATED APPLICATIONS

This application claims priority to U.S. Provisional Application Ser. No. 63/645,186 filed May 10, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-11A are cross-sectional side views of various stages of manufacturing the semiconductor device structure taken along line A-A of FIG. 6, in accordance with some embodiments.

FIGS. 7B-11B are cross-sectional side views of various stages of manufacturing the semiconductor device structure taken along line B-B of FIG. 6, in accordance with some embodiments.

FIGS. 7C-11C are cross-sectional side views of various stages of manufacturing the semiconductor device structure taken along line C-C of FIG. 6, in accordance with some embodiments.

FIGS. 12A-12E are cross-sectional side views of various stages of manufacturing the semiconductor device structure, in accordance with some embodiments.

FIG. 12C-1 is a schematic diagram of a portion of a fluorine-containing layer of the semiconductor device structure, in accordance with some embodiments.

FIGS. 13A-13G are cross-sectional side views of various stages of manufacturing the semiconductor device structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

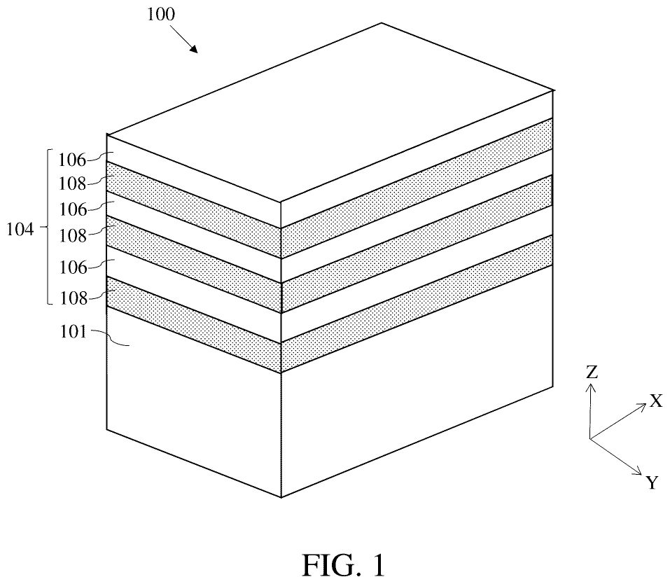

FIGS. 1-12E show exemplary processes for manufacturing a semiconductor device structure 100 according to embodiments of the present disclosure. It is understood that additional operations can be provided before, during, and after processes shown by FIGS. 1-12E, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 9 nm. Each second semiconductor layer 108 may have a thickness that is equal, less, or greater than the thickness of the first semiconductor layer 106. In some embodiments, each second semiconductor layer 108 has a thickness in a range between about 4 nm and about 14 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the number of first semiconductor layers 106 ranges from two to 10.

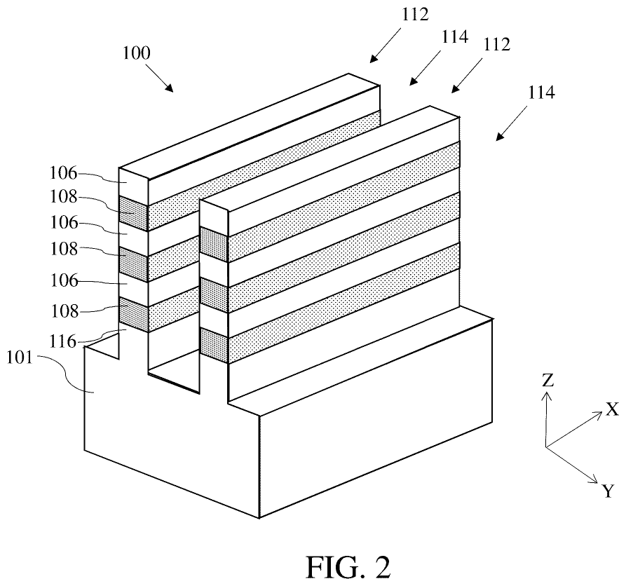

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

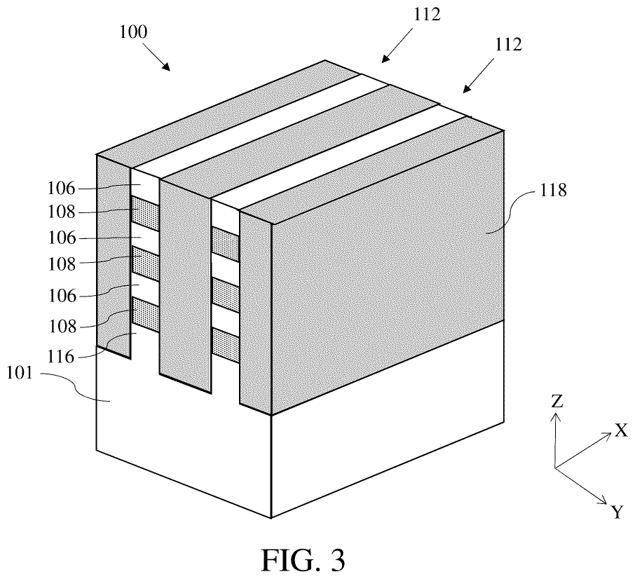

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

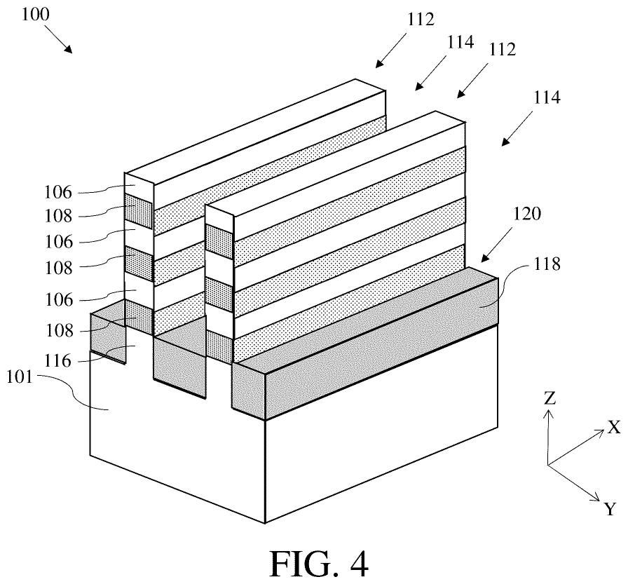

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

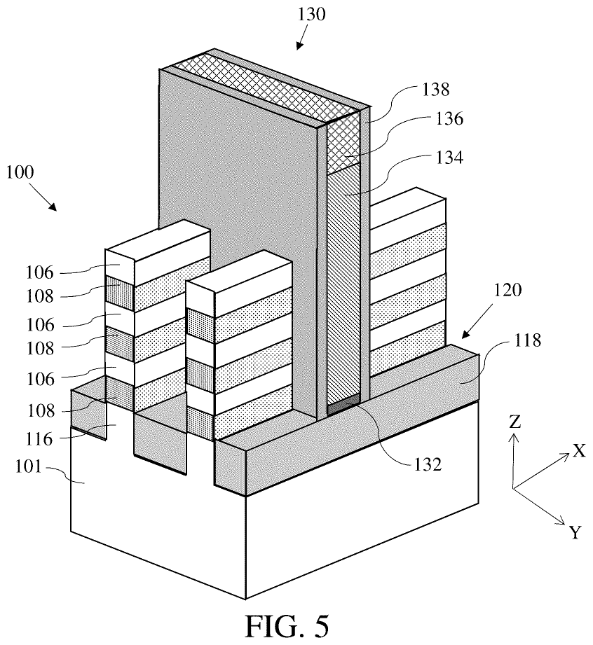

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

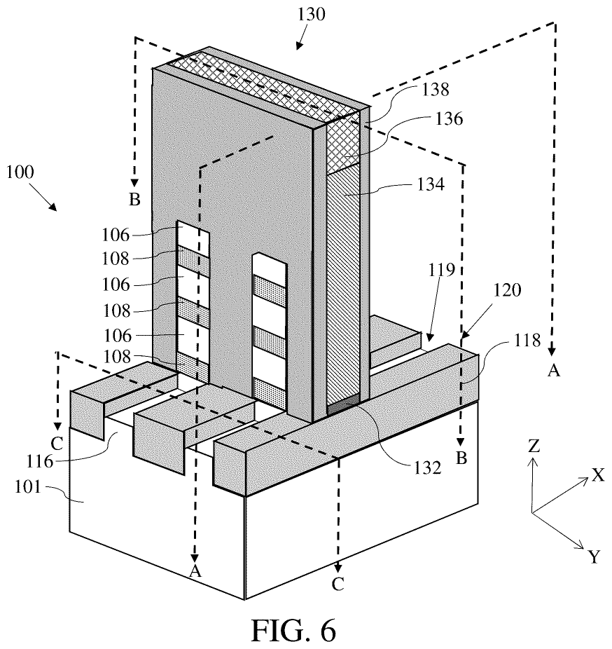

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to the first and second semiconductor layers 106, 108. The etch process may be a dry etch, such as a RIE, NBE, or the like, or a wet etch, such as using tetramethyalammonium hydroxide (TMAH), ammonium hydroxide (NH₄OH), or any suitable etchant.

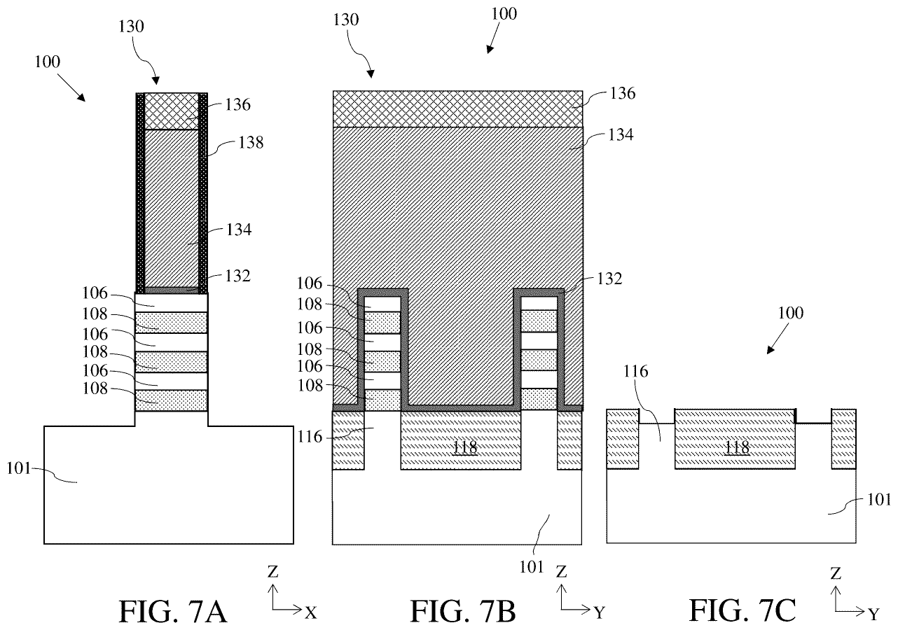

FIGS. 7A, 7B, and 7C are cross-sectional side views of the semiconductor device structure 100 taken along line A-A, line B-B, and line C-C of FIG. 6, respectively.

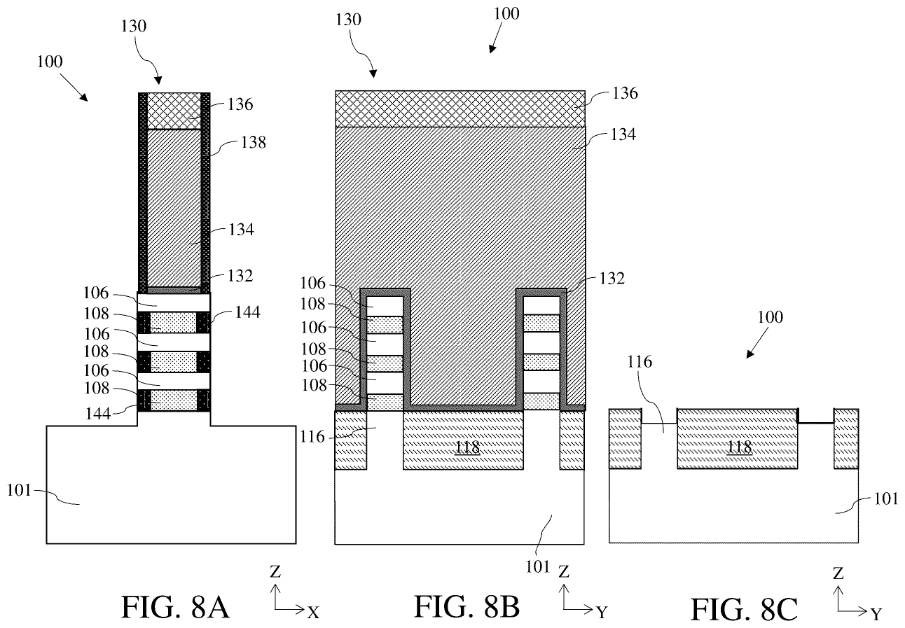

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

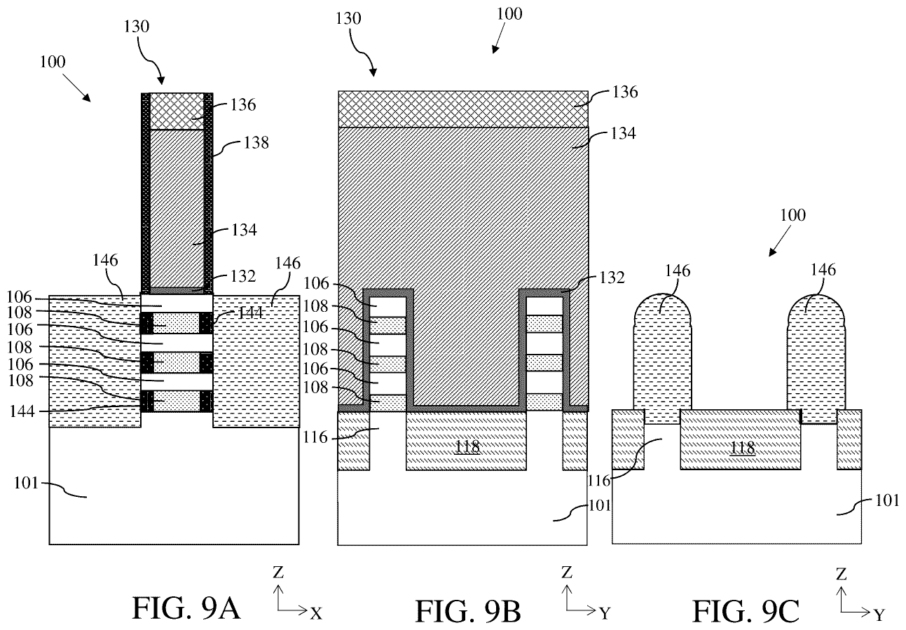

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portion 116. The S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

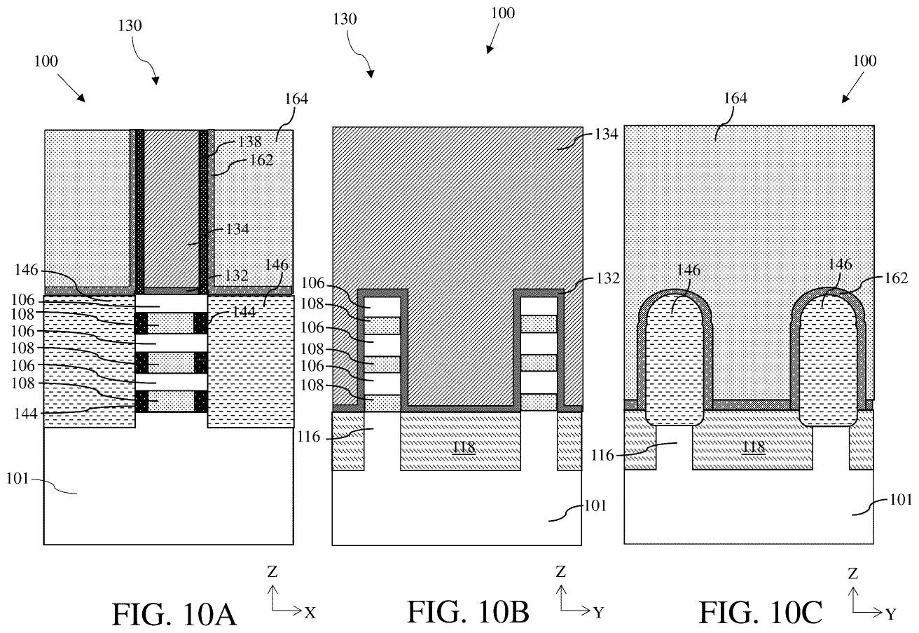

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B.

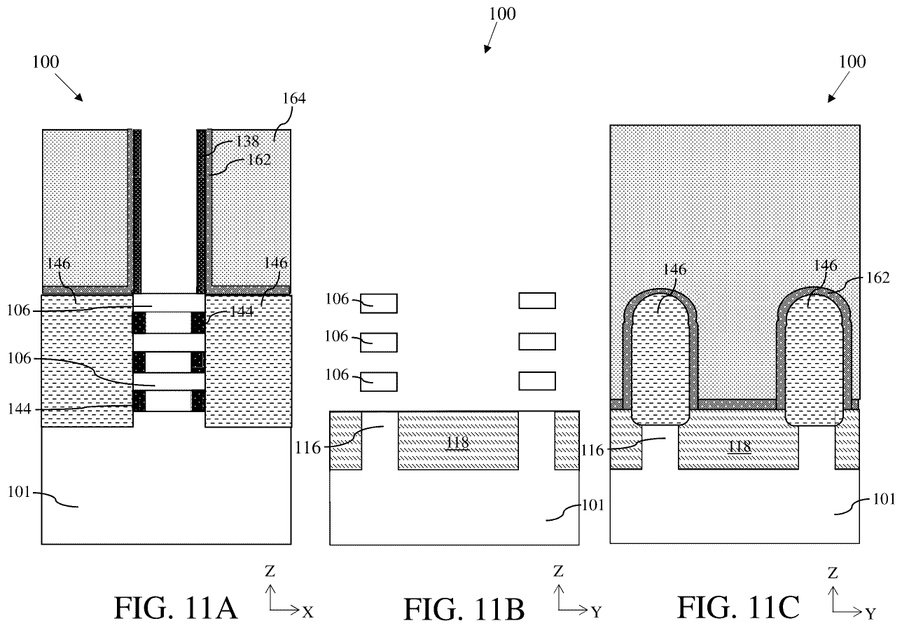

FIGS. 11A, 11B, and 11C are cross-sectional side views of one of various stages of manufacturing the semiconductor device structure 100 taken along line A-A, line B-B, and line C-C of FIG. 6, respectively, in accordance with some embodiments. As shown in FIGS. 11A and 11B, the sacrificial gate structure 130 and the second semiconductor layers 108 are removed. The removal of the sacrificial gate structure 130 and the semiconductor layers 108 forms an opening between gate spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

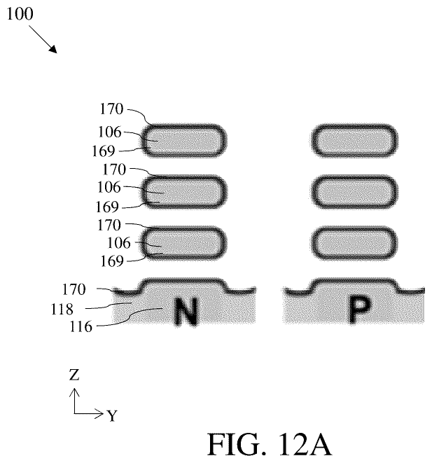

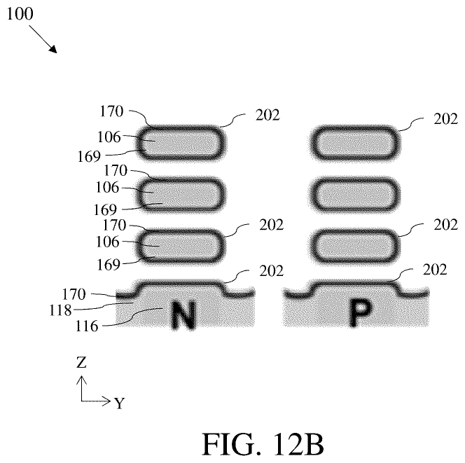

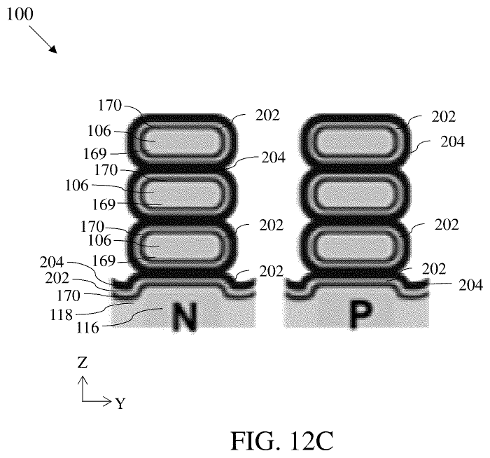

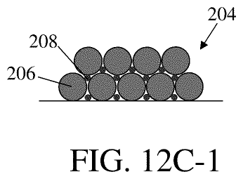

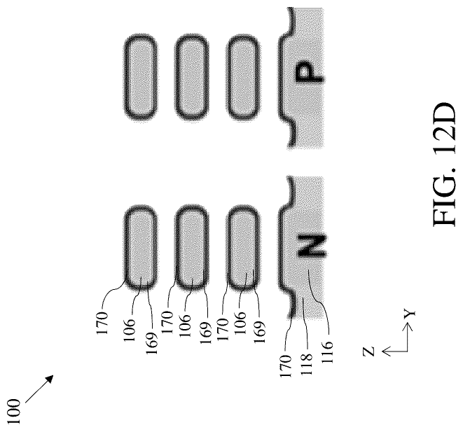

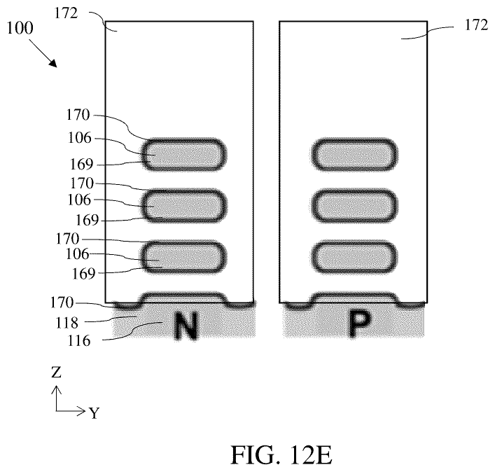

FIGS. 12A-12E are cross-sectional side views of various stages of manufacturing the semiconductor device structure 100, in accordance with some embodiments. As shown in FIG. 12A, after the formation of the nanostructure channels (i.e., the exposed portions of the first semiconductor layers 106), an interfacial layer (IL) 169 is formed to surround the exposed portions of the first semiconductor layers 106 and the substrate portion 116, and a gate dielectric layer 170 is formed on the IL 169. In some embodiments, the IL 169 is selectively formed on the semiconductor materials of the first semiconductor layers 106 and the substrate portion 116, and the gate dielectric layer 170 is also formed on the insulating material 118. In some embodiments, the IL 169 is an oxide layer, such as silicon oxide. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HTIO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique.

In some embodiments, the first semiconductor layers 106 located on the left side of FIG. 12A are channels of an NMOS device, and the first semiconductor layers 106 located on the right side of FIG. 12A are channels of a PMOS device adjacent the NMOS device.

In some embodiments, a dipole process is performed to introduce dipole materials into the gate dielectric layer 170. The dipole process may include depositing a dipole layer (not shown) on the gate dielectric layer 170 and performing a thermal process to drive the dipole material in the dipole layer into the gate dielectric layer 170. In some embodiments, different dipole layers are formed for NMOS devices and PMOS devices. For example, a dipole material suitable for NMOS devices may include lanthanoid oxide (La₂O₃), yttrium oxide (Y₂O₃), titanium oxide (TiO₂), other n-type dipole material, or combinations thereof; and a dipole material suitable for PMOS devices may include aluminum oxide (Al₂O₃), TiO₂, other p-type dipole material, or combinations thereof. After the thermal process, the dipole layer is removed to expose the gate dielectric layer 170.

In some embodiments, after the formation of the gate dielectric layer 170 (and the dipole process in some embodiments), a fluorination process is performed to introduce fluorine into the gate dielectric layer 170 and the IL 169. The fluorine may repair or occupy oxygen vacancies in the gate dielectric layer 170 and the IL 169, and the fluorine in the gate dielectric layer 170 and the IL 169 may suppress interdiffusion of elements between adjacent NMOS device and PMOS device. The fluorination process may be a gas soak process using a fluorine-containing gas, such as NF₃ or WF₆. However, because there are multiple levels of the gate dielectric layer 170 and the IL 169, the fluorine concentration in the gate dielectric layer 170 and the IL 169 at different locations may not be uniform. The portions of the gate dielectric layer 170 and the portions of the IL 169 located thereunder that are more exposed to the fluorine-containing gas may have a higher fluorine concentration than the portions of the gate dielectric layer 170 and the portions of the IL 169 located thereunder that are less exposed to the fluorine-containing gas. For example, the fluorine concentration in the gate dielectric layer 170 surrounding the topmost first semiconductor layer 106 may be substantially greater than the fluorine concentration in the gate dielectric layer 170 surrounding the bottommost first semiconductor layer 106. Furthermore, the fluorine concentration in portions of the gate dielectric layer 170 located on the sides of the first semiconductor layers 106 may be substantially greater than the fluorine concentration in portions of the gate dielectric layer 170 located between vertically adjacent first semiconductor layers 106. In addition, the fluorine concentration in the gate dielectric layer 170 and the IL 169 in NMOS device may be substantially different from the fluorine concentration in the gate dielectric layer 170 and the IL 169 in PMOS device due to different critical dimensions of subsequently formed gate electrode layers for NMOS device and PMOS device. The non-uniform fluorine concentration in the gate dielectric layer 170 may lead to reduced standard deviation of threshold voltage (Vt sigma). Embodiments of the present disclosure provide a process to uniformly incorporate fluorine into the gate dielectric layer 170.

As shown in FIG. 12B, an adhesion layer 202 is formed on the gate dielectric layer 170. In some embodiments, the adhesion layer 202 is a conformal layer formed by a conformal process, such as an ALD process. The adhesion layer 202 may include any material that can adhere to the subsequently formed fluorine-containing layer 204. In some embodiments, the adhesion layer 202 is made of or includes TiN.

As shown in FIG. 12C, the fluorine-containing layer 204 is deposited on the adhesion layer 202. In some embodiments, the adhesion layer 202 is oxidized if the semiconductor device structure 100 is exposed to air, and a treatment process may be performed to remove the oxidized portion of the adhesion layer 202. In some embodiments, the adhesion layer 202 includes TiN, and the surface portion of the adhesion layer 202 may be oxidized to form a TiOₓ layer. The treatment process may be a gas soaking process using a gas that can break the Ti—O bonds. Thus, the TiOₓ is reduced by the removal of the oxygen. In some embodiments, the gas of the gas soaking process may be B₂H₆ or WF₆, and the gas flow rate may range from about 800 standard cubic centimeters per minute (sccm) to about 900 sccm. The gas soaking process may have a time duration ranging from about 10 seconds to about 20 seconds.

After the treatment process, the fluorine-containing layer 204 is deposited. In some embodiments, the processing chamber for performing the treatment process and the processing chamber for performing the deposition of the fluorine-containing layer 204 are part of a cluster tool, and the semiconductor device structure 100 is not exposed to air between the treatment process and the deposition process. In other words, the treatment process and the deposition process are performed on the semiconductor device structure 100 without breaking vacuum.

In some embodiments, the fluorine-containing layer 204 is formed by ALD in order to have a uniform fluorine concentration within the fluorine-containing layer 204. The ALD process to form the fluorine-containing layer 204 may include introducing a first precursor into a processing chamber, and molecules of the first precursor are adsorbed on the exposed surfaces of the semiconductor device structure 100 until the surfaces are saturated with the molecules of the first precursor. The saturated molecules of the first precursor form an atomic layer of molecules of the first precursor. For example, the surface of the adhesion layer 202 is saturated with the molecules of the first precursor, and an atomic layer of the molecules of the first precursor is formed on the adhesion layer 202. In some embodiments, the first precursor includes WF₆ gas, and the gas flow rate may range from about 20 sccm to about 100 sccm, such as from about 50 sccm to about 65 sccm with a pulse time of about 0.5 seconds to about 3 seconds, such as from about 1.3 seconds to about 1.7 seconds. The flow rate of the first precursor ensures that the surface of the adhesion layer 202 are saturated with the molecules of the first precursor. For example, the surface of the adhesion layer 202 is saturated with WF₆ molecules. The saturated WF₆ molecules may form an atomic layer of WF₆ on the adhesion layer 202.

Next, the processing chamber is purged to remove the first precursor from the processing chamber. A second precursor is then introduced into the processing chamber. The second precursor reacts with the atomic layer of the molecules of the first precursor to form a layer. In some embodiments, the second precursor is B₂H₆ or SiH₄, and the second precursor breaks the bonds of the molecules of the first precursor. For example, the second precursor breaks the W—F bonds of the atomic WF₆ layer to form a tungsten nucleation layer. In some embodiments, some fluorine atoms from the broken W—F bonds are removed from the surface of the atomic layer, while some fluorine atoms from the broken W—F bonds are trapped between adjacent tungsten atoms. The number of trapped fluorine atoms may be substantially constant within the tungsten nucleation layer due to the structure of the WF₆ atomic layer. As a result, the fluorine concentration within the tungsten nucleation layer may be substantially uniform.

In some embodiments, the second precursor may have a flow rate ranging from about 200 sccm to about 1500 sccm, such as from about 800 sccm to about 900 sccm with a pulse time of about 0.5 seconds to about 3 seconds, such as from about 1.7 seconds to about 2.1 seconds. The flow rate of the second precursor ensures that the W—F bonds are broken so a constant number of fluorine atoms are within the tungsten nucleation layer.

Next, another purge process may be performed to remove the second precursor from the processing chamber. The cycle of introducing the first precursor into the processing chamber, purging the processing chamber, introducing the second precursor into the processing chamber, and purging the processing chamber may be repeated until the fluorine-containing layer 204 reaches a predetermined thickness. In some embodiments, the number of cycles of the ALD process ranges from about six to about eight, and the fluorine-containing layer 204 may have a thickness ranging from about 18 angstroms to about 26 angstroms. The fluorine atoms from the fluorine-containing layer 204 are to be diffused into the gate dielectric layer 170 and the IL 169. Thus, if the thickness of the fluorine-containing layer 204 is less than about 18 angstroms, the number of fluorine atoms in the fluorine-containing layer 204 is not sufficient to be diffused into the gate dielectric layer 170 and the IL 169. On the other hand, if the thickness of the fluorine-containing layer 204 is greater than about 26 angstroms, the manufacturing cost is increased without significant advantage. In some embodiments, each cycle of the ALD process may be performed at a processing temperature ranging from about 280 degrees Celsius to about 320 degrees Celsius and at a processing pressure ranging from about four torr to about eight torr.

FIG. 12C-1 is a schematic diagram of a portion of the fluorine-containing layer 204 of the semiconductor device structure 100, in accordance with some embodiments. In some embodiments, as shown in FIG. 12C-1, the fluorine-containing layer 204 includes the fluorine atoms 208 trapped between the atoms 206 of the first precursor, such as tungsten atoms. The number of fluorine atoms 208 trapped between the atoms 206 may be substantially constant for each cycle of the ALD process described above. As a result, the fluorine concentration of the fluorine-containing layer 204 may be substantially constant with respect to the location of the fluorine-containing layer 204. For example, the portion of the fluorine-containing layer 204 surrounding the topmost first semiconductor layer 106 may have the same fluorine concentration as the portion of the fluorine-containing layer 204 surrounding the bottommost first semiconductor layer 106. Furthermore, the portions of the fluorine-containing layer 204 located on the sides of the first semiconductor layers 106 may have the same fluorine concentration as the portions of the fluorine-containing layer 204 located between vertically adjacent first semiconductor layers 106. In addition, the portion of the fluorine-containing layer 204 in the NMOS device may have the same fluorine-concentration as the portion of the fluorine-containing layer 204 in the PMOS device. In some embodiments, the fluorine-containing layer 204 is a tungsten layer having a substantially constant fluorine concentration therewithin.

Next, an annealing process is performed to drive the fluorine from the fluorine-containing layer 204 into the gate dielectric layer 170 and the IL 169. The annealing process may be any suitable annealing process, such as a single wafer anneal or a batch anneal. The annealing process may be performed at a processing temperature ranging from about 480 degrees Celsius to about 520 degrees Celsius for a time period ranging from about 10 seconds to about 20 seconds. The fluorine atoms in the fluorine-containing layer 204 are diffused through the adhesion layer 202 and into the gate dielectric layer 170. In some embodiments, the fluorine atoms also diffuse through the gate dielectric layer 170 into the IL 169. Because the fluorine concentration in the fluorine-containing layer 204 is substantially uniform, the fluorine concentration in the gate dielectric layer 170 and the IL 169 is substantially uniform. Better fluorine uniformity may result in reduced Vt sigma and reduced or alleviated metal boundary effect, which may occur when elements (e.g., dipole materials) in the gate dielectric layers 170 and the ILs 169 at a boundary between a NMOS device and a PMOS device intermix with each other, which may result in Vt shift (offset from target). In some embodiments, both NMOS device and PMOS device have about 30 to about 50 mV metal boundary effect gain as a result of the uniform fluorine concentration in the gate dielectric layer 170 and the IL 169, compared to the 55 mV to about 80 mV metal boundary effect gain using conventional processes to incorporate fluorine into the gate dielectric layer 170 and the IL 169.

As shown in FIG. 12D, after the annealing process, the fluorine-containing layer 204 and the adhesion layer 202 are removed. The fluorine-containing layer 204 and the adhesion layer 202 may be removed by any suitable process. In some embodiments, a selective etching process is performed to remove the fluorine-containing layer 204 and the adhesion layer 202. The selective etching process may be a dry etching process or a wet etching process and does not substantially affect the gate dielectric layer 170 and the ILD layer 164.

As shown in FIG. 12E, a gate electrode layer 172 is formed on gate dielectric layer 170. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. In some embodiments, the gate electrode layer 172 for the NMOS device and the gate electrode layer 172 for the PMOS device are made of different materials and are formed at different times using one or more masks (not shown). For example, the gate electrode layer 172 for the NMOS device may include one or more n-type work function layers. The one or more n-type work function layers may include any suitable n-type work function material, such as Ti, Al, Ag, Mn, Zr, TiAl, TiAlC, TaC, TaCN, TaSiN, TaAl, TaAIC, TiAlN, other n-type work function material, or combinations thereof. The gate electrode layer 172 for the PMOS device may include one or more p-type work function layers. The one or more p-type work function layers may include any suitable p-type work function material, such as TiN, TaN, Ru, Mo, Al, WN, ZrSi₂, MoSi₂, TaSi₂, NiSi₂, WN, other p-type work function material, or combinations thereof. The n-type work function layers and the p-type work function layers may be conformal layers formed by conformal processes, such as ALD. The gate electrode layer 172 may include a bulk metal for both NMOS device and PMOS device. In some embodiments, the bulk metal includes aluminum, copper, titanium, tantalum, tungsten, cobalt, molybdenum, or other suitable metal. The bulk metal may be formed by CVD, ALD, electro-plating, or other suitable deposition technique. The gate electrode layer 172 may be also deposited over the upper surface of the ILD layer 164. The gate electrode layer 172 formed over the ILD layer 164 is then removed by using, for example, CMP, until the top surface of the ILD layer 164 is exposed. The IL 169, the gate dielectric layer 170, and the gate electrode layer 172 may be collectively referred to as a gate structure.

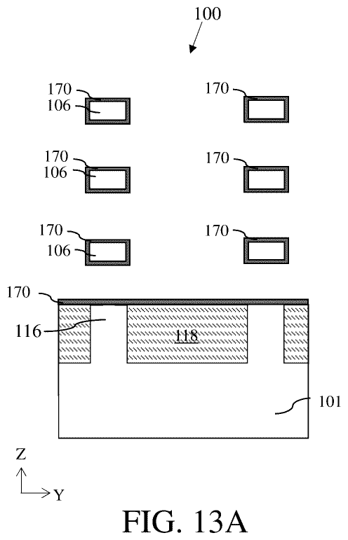

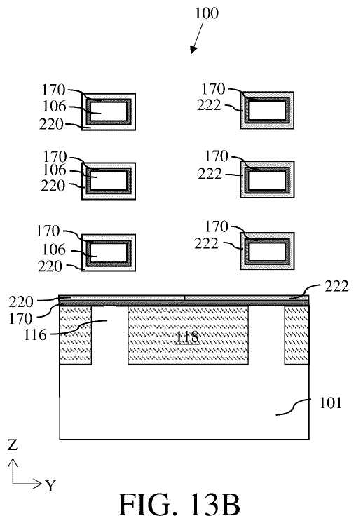

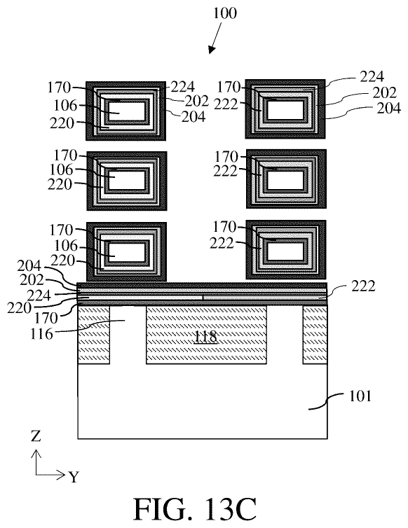

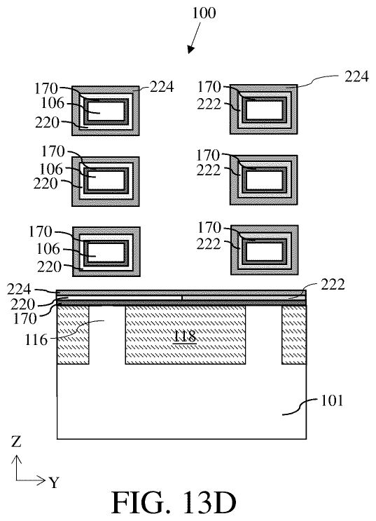

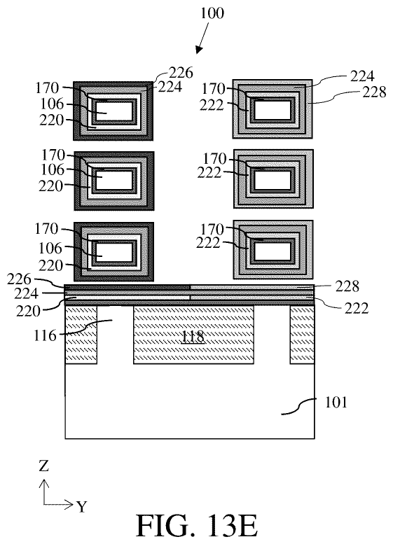

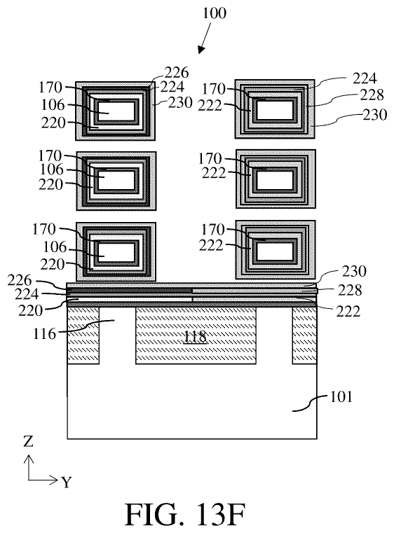

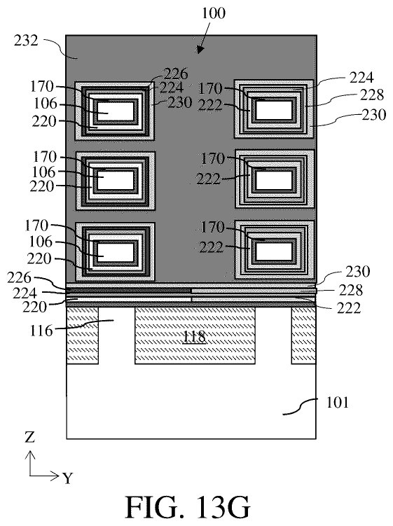

FIGS. 13A-13G are cross-sectional side views of various stages of manufacturing the semiconductor device structure 100, in accordance with alternative embodiments. As shown in FIG. 13A, the gate dielectric layer 170 is formed to surround the first semiconductor layers 106. The IL 169 is omitted in FIGS. 13A-13G for clarity. Next, as shown in FIG. 13B, an n-type work function layer 220 is formed on portions of the gate dielectric layer 170 in an NMOS device, and a p-type work function layer 222 is formed on portions of the gate dielectric layer 170 in a PMOS device. The n-type work function layer 220 and the p-type work function layer 222 may include different materials and may be formed at different times using one or more masks (not shown). The n-type work function layer 220 includes an n-type work function material as described above, and the p-type work function layer 222 includes a p-type work function material as descried above. In some embodiments, the n-type work function layer 220 includes TiAl, and the p-type work function layer 222 includes TiN. The n-type work function layer 220 and the p-type work function layer 222 may be conformal layers formed by a conformal process, such as ALD.

As shown in FIG. 13C, a cap layer 224 is deposited on the n-type work function layer 220 and the p-type work function layer 222, the adhesion layer 202 is deposited on the cap layer 224, and the fluorine-containing layer 204 is deposited on the adhesion layer 202. The cap layer 224 includes a material having a high etch selectivity with respect to the adhesion layer 202. In some embodiments, the cap layer 224 is a silicon layer, such as an amorphous silicon layer or a polycrystalline silicon layer. The adhesion layer 202 and the fluorine-containing layer 204 may be deposited as described above so the fluorine concentration in the fluorine-containing layer 204 is substantially uniform.

Next, the annealing process is performed to drive fluorine into the cap layer 224, the work function layers 220, 222, the gate dielectric layer 170, and the IL 169. Because the fluorine concentration in the fluorine-containing layer 204 is uniform, the concentrations of fluorine in the cap layer 224, the work function layers 220, 222, the gate dielectric layer 170, and the IL 169 are substantially uniform. The work function layers 220, 222 with substantially uniform fluorine concentrations may further reduce metal boundary effect. In some embodiments, the fluorine concentration of the work function layer 220 (or the work function layer 222) is substantially greater than the fluorine concentration of the gate dielectric layer 170, which is substantially greater than the fluorine concentration of the IL 169.

As shown in FIG. 13D, the fluorine-containing layer 204 and the adhesion layer 202 are removed. The cap layer 224 protects the n-type work function layer 220 and the p-type work function layer 222 from the etch process that removes the fluorine-containing layer 204 and the adhesion layer 202.

As shown in FIG. 13E, another n-type work function layer 226 is deposited on portions of the cap layer 224 in the NMOS device, and another p-type work function layer 228 is deposited on portions of the cap layer 224 in the PMOS device. Similar to the n-type work function layer 220 and p-type work function layer 222, the n-type work function layer 226 and the p-type work function layer 228 include different materials and are formed at different times using one or more masks (not shown).

In some embodiments, the n-type work function layer 226 and the n-type work function layer 220 include different materials, and the fluorine may affect the two layers differently. For example, when the n-type work function layer 220 is incorporated with fluorine, the metal boundary effect is reduced. However, the fluorine may negatively affect the electrical properties or physical properties of the n-type work function layer 226. Similarly, the p-type work function layer 228 and the p-type work function layer 222 include different materials, and the fluorine may affect the two layers differently. For example, when the p-type work function layer 222 is incorporated with fluorine, the metal boundary effect is reduced. However, the fluorine may negatively affect the electrical properties or physical properties of the p-type work function layer 228. Thus, in some embodiments, the n-type work function layer 226 and the p-type work function layer 228 are deposited after the incorporation of fluorine into the various layers. In some embodiments, the n-type work function layer 226 and the p-type work function layer 228 are substantially free of fluorine. In some embodiments, the fluorine concentration decreases in a direction from the cap layer 224 to the gate dielectric layer 170 and in a direction from the cap layer 224 to the subsequently formed bulk metal 232 (FIG. 13G). In other words, in some embodiments, the concentration of fluorine is the highest in the cap layer 224 and decreases both inward and outward thereof. In some embodiments, the fluorine concentration of the n-type work function layer 220 is substantially greater than the fluorine concentration of the n-type work function layer 226, and the fluorine concentration of the p-type work function layer 222 is substantially greater than the fluorine concentration of the p-type work function layer 228. In some embodiments, the n-type work function layer 226 and the p-type work function layer 228 are not present, and a single work function layer is deposited on the cap layer 224. The single work function layer may be a TiN layer. The fluorine concentration in the single work function layer may be substantially less than the fluorine concentration in the n-type work function layer 220 or the p-type work function layer 222. In some embodiments, the single work function layer is free of fluorine.

In some embodiments, the n-type work function layer 220 includes two or more layers that are fluorinated, and the n-type work function layer 226 includes two or more layers that are not fluorinated. Similarly, in some embodiments, the p-type work function layer 222 includes two or more layers that are fluorinated, and the p-type work function layer 228 includes two or more layers that are not fluorinated, in some embodiments.

As shown in FIG. 13F, another adhesion layer 230 is deposited on the n-type work function layer 226 and the p-type work function layer 228. The adhesion layer 230 may include the same material as the adhesion layer 202 and may be formed by the same process as the adhesion layer 202. Next, a bulk metal 232 is deposited on the adhesion layer 230. In some embodiments, the bulk metal 232 does not adhere to the n-type work function layer 226 and the p-type work function layer 228, and the adhesion layer 230 helps to adhere to the bulk metal 232. In some embodiments, the bulk metal 232 is made of or includes tungsten. The IL 169, the gate dielectric layer 170, the work function layers 220, 226 (or work function layers 222, 228), the cap layer 224, the adhesion layer 230, and the bulk metal 232 may be collectively referred to as a gate structure. In some embodiments, the adhesion layer 230 is optional and not present in the gate structure.

Embodiments of the present disclosure provide a method to form a semiconductor device structure 100. The method includes using an ALD process to deposit a fluorine-containing layer 204, so the fluorine concentration within the fluorine-containing layer 204 is substantially uniform. The fluorine-containing layer 204 may be deposited at any location within the gate structure, and subsequent annealing process drives fluorine in the fluorine-containing layer 204 into layers, such as the gate dielectric layer 170 and the IL 169, located under the fluorine-containing layer 204. Some embodiments may achieve advantages. For example, the fluorine concentrations in the gate dielectric layer 170 and the IL 169 are substantially uniform as a result of the fluorine-containing layer 204 having uniform fluorine concentration. The gate dielectric layer 170 and the IL 169 having uniform fluorine concentrations can lead to reduced metal boundary effect and reduced Vt sigma.

An embodiment is a method. The method includes forming a fin structure from a substrate, and the fin structure includes a plurality of semiconductor layers. The method further includes depositing a gate dielectric layer around a portion of each semiconductor layer of the plurality of semiconductor layers, depositing an adhesion layer on the gate dielectric layer, and the adhesion layer surrounds the portion of each semiconductor layer of the plurality of semiconductor layers. The method further includes depositing a fluorine-containing layer on the adhesion layer, and the fluorine-containing layer surrounds the portion of each semiconductor layer of the plurality of semiconductor layers. The method further includes performing an annealing process on the fluorine-containing layer, removing the fluorine-containing layer and the adhesion layer, and forming a gate electrode layer on the gate dielectric layer.

Another embodiment is a method. The method includes forming a first fin structure and a second fin structure from a substrate, the first fin structure includes a first plurality of semiconductor layers, and the second fin structure includes a second plurality of semiconductor layers. The method further includes depositing a gate dielectric layer around a portion of each of the first plurality of semiconductor layers, depositing a first work function layer on portions of the gate dielectric layer around the portion of each of the first plurality of semiconductor layers, depositing an adhesion layer over the first work function layer, depositing a fluorine-containing layer on the adhesion layer, performing an annealing process on the fluorine-containing layer, removing the fluorine-containing layer and the adhesion layer, depositing a second work function layer over the first work function layer, and depositing a bulk metal over the second work function layer.

A further embodiment is a semiconductor device structure. The structure includes a substrate portion extending from a substrate, a semiconductor layer disposed over the substrate portion, a gate dielectric layer surrounding at least a portion of the semiconductor layer, and the gate dielectric layer has a first fluorine concentration. The structure further includes a first work function layer surrounding the gate dielectric layer, and the first work function layer has a second fluorine concentration greater than the first fluorine concentration. The structure further includes a second work function layer surrounding the first work function layer, and the second work function layer has a third fluorine concentration less than the second fluorine concentration.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a fin structure from a substrate, wherein the fin structure includes a plurality of semiconductor layers;
depositing a gate dielectric layer around a portion of each semiconductor layer of the plurality of semiconductor layers;
depositing an adhesion layer on the gate dielectric layer, wherein the adhesion layer surrounds the portion of each semiconductor layer of the plurality of semiconductor layers;
depositing a fluorine-containing layer on the adhesion layer, wherein the fluorine-containing layer surrounds the portion of each semiconductor layer of the plurality of semiconductor layers;
performing an annealing process on the fluorine-containing layer;
removing the fluorine-containing layer and the adhesion layer; and
forming a gate electrode layer on the gate dielectric layer.

2. The method of claim 1, wherein the fluorine-containing layer is formed by an atomic layer deposition process.

3. The method of claim 2, wherein the atomic layer deposition process comprises a plurality of cycles, and each cycle comprises introducing a first precursor into a processing chamber and introducing a second precursor into the processing chamber.

4. The method of claim 3, wherein the first precursor comprises WF₆, and the second precursor comprises B₂H₆ or SiH₄.

5. The method of claim 3, wherein the first precursor has a flow rate ranging from about 20 standard cubic centimeters per minute (sccm) to about 100 sccm, and the second precursor has a flow rate ranging from 200 sccm to about 1500 sccm.

6. The method of claim 1, wherein the fluorine-containing layer 204 has a thickness ranging from about 18 angstroms to about 26 angstroms.

7. The method of claim 1, further comprising performing a treatment process after depositing the adhesion layer and prior to depositing the fluorine-containing layer.

8. The method of claim 7, wherein the treatment process removes an oxide from the adhesion layer.

9. A method, comprising:
forming a first fin structure and a second fin structure from a substrate, wherein the first fin structure includes a first plurality of semiconductor layers, and the second fin structure includes a second plurality of semiconductor layers;
depositing a gate dielectric layer around a portion of each of the first plurality of semiconductor layers;
depositing a first work function layer on portions of the gate dielectric layer around the portion of each of the first plurality of semiconductor layers;
depositing an adhesion layer over the first work function layer;
depositing a fluorine-containing layer on the adhesion layer;
performing an annealing process on the fluorine-containing layer;
removing the fluorine-containing layer and the adhesion layer;
depositing a second work function layer over the first work function layer; and
depositing a bulk metal over the second work function layer.

10. The method of claim 9, wherein the gate dielectric layer is deposited around a portion of each of the second plurality of semiconductor layers.

11. The method of claim 10, further comprising depositing a third work function layer on portions of the gate dielectric layer around the portion of each of the second plurality of semiconductor layers.

12. The method of claim 11, wherein the adhesion layer is deposited over the third work function layer.

13. The method of claim 12, further comprising depositing a fourth work function layer over the third work function layer after the removal of the fluorine-containing layer.

14. The method of claim 13, wherein the first and second work function layers are n-type work function layers, and the third and fourth work function layers are p-type work function layers.

15. The method of claim 9, further comprising depositing a cap layer on the first work function layer, wherein the adhesion layer is deposited on the cap layer.

16. The method of claim 15, wherein the cap layer comprises silicon.

17. A semiconductor device structure, comprising:
a substrate portion extending from a substrate;
a semiconductor layer disposed over the substrate portion;
a gate dielectric layer surrounding at least a portion of the semiconductor layer, wherein the gate dielectric layer has a first fluorine concentration;
a first work function layer surrounding the gate dielectric layer, wherein the first work function layer has a second fluorine concentration greater than the first fluorine concentration; and
a second work function layer surrounding the first work function layer, wherein the second work function layer has a third fluorine concentration less than the second fluorine concentration.

18. The semiconductor device structure of claim 17, further comprising a cap layer disposed between the first and second work function layers, wherein the cap layer has a fourth fluorine concentration greater than the second fluorine concentration.

19. The semiconductor device structure of claim 18, further comprising an adhesion layer disposed on the second work function layer.

20. The semiconductor device structure of claim 19, further comprising a bulk metal disposed on the adhesion layer.
